(19) United States
(12) Patent Application Publication
(10) Pub. No.: US 2026/0010671 A1
(43) Pub. Date: Jan. 8, 2026

(54) Live Digital Map Driven Distribution Network Planning Scheme Intelligent Evaluation Method and System

(71) Applicant: Guizhou Power Grid Co., Ltd., Guiyang (CN)

(72) Inventors: Ning LUO, Guiyang (CN); Mao MIAO, Guiyang (CN); Molin HE, Guiyang (CN); Bo CHEN, Guiyang (CN); Chang XU, Guiyang (CN); Jiahuan LONG, Guiyang (CN); Qingyu ZHAO, Guiyang (CN); Jinsen LIU, Guiyang (CN); Jianshuai GUO, Guiyang (CN); Fei ZHENG, Guiyang (CN); Jie WANG, Guiyang (CN); Yu ZHANG, Guiyang (CN); Ludong CHEN, Guiyang (CN); Pengcheng ZHANG, Guiyang (CN); Zhen LI, Guiyang (CN)

(21) Appl. No.: 19/016,896

(22) Filed: Jan. 10, 2025

Related U.S. Application Data
(63) Continuation of application No. PCT/CN2024/138058, filed on Dec. 10, 2024.

(30) Foreign Application Priority Data
Jul. 8, 2024 (CN) 2024109053224

(51) Int. Cl. G06F 30/18

(52) U.S. Cl. CPC G06F 30/18

(57) ABSTRACT

The present invention discloses a live digital map driven distribution network planning scheme intelligent evaluation method and system, relating to the field of intelligent distribution network planning and evaluation. The method comprises: acquiring a live digital map image, acquiring plot information by using U-net convolutional neural network plot identification strategy based on a stacked auto-encoder, and selecting alternative planning schemes according to index hierarchy structures and data driving evaluation. By adopting the present invention, the precision and efficiency of planning scheme evaluation is improved.

### CROSS-REFERENCE TO RELATED APPLICATIONS

The present application claims priority to Chinese Patent Application No. 2024109053224, filed on Jul. 8, 2024, the entire disclosure of which is incorporated herein by reference.

### TECHNICAL FIELD

The present invention relates to the field of intelligent distribution network planning evaluation, and in particular relates to a live digital map driven distribution network planning scheme intelligent evaluation method and system.

### BACKGROUND

Nowadays, the evaluation of distribution network planning schemes is more and more important. With the advance of energy transformation and the change of energy consumption pattern, the traditional power distribution system has been difficult to meet the requirement of increasing complexity and high efficiency. Therefore, by systematically evaluating different planning schemes, it is possible to ensure the optimal performance of the power distribution system in terms of efficiency, reliability and sustainability.

The traditional distribution network planning evaluation has defects, such as inconsistent planning standards, subjective influence and chaotic operation and management after planning, which can no longer meet the basic requirements of a modern distribution network. Although the current distribution network evaluation methods aim to improve the evaluation accuracy and reliability of distribution network planning schemes, so as to provide reference for practical application, there are problems that too much manual intervention is required, and the efficiency of planning evaluation is restricted. The machine learning method widely used in the field of load forecasting has not been fully utilized in the fully automated distribution network evaluation, and the intelligent level and accuracy of distribution network evaluation need to be further improved.

### SUMMARY

In view of the existing problems above, the present invention is disclosed.

Therefore, the technical problem solved by the present invention is how to improve the efficiency, reliability and adaptability of a power distribution system through effective distribution network planning scheme evaluation.

In order to solve the above technical problems, the present invention provides the following technical solutions:

On a first aspect, an embodiment of the present invention provides a live digital map driven distribution network planning scheme intelligent evaluation method, including:
acquiring live map data and plot type information in a map as original data set, establishing a U-Net convolutional neural network by means of using a stacked auto-encoder, and taking the original data set as the input of convolutional neural network training;
training the convolutional neural network by means of using an awakening-sleep mechanism;
inputting live map data of an region to be planned into the convolutional neural network by means of using convolutional neural network parameters obtained through training of the awakening-sleep mechanism, so as to obtain area data of each plot type;
multiplying a typical load curve and a load density of each plot acquired in advance with the obtained plot area, so as to obtain the load curve of each plot;
calculating, based on the load curve of each plot, four indexes of rate of equipment utilization, power supply radius, installed capacity of renewable energy and peak-valley difference for each alternative planning scheme; and
calculating weights of four indexes by means of using a data driven information entropy weight calculating method, and calculating the final score of an alternative planning scheme, thereby completing evaluation.

As an optimal solution of the live digital map driven distribution network planning scheme intelligent evaluation method,
training the convolutional neural network by means of using the awakening-sleep mechanism includes:
dividing training into two phases of awakening and sleep; setting Ri as the ith layer of the convolutional neural network, and L as the number of layers of the convolutional neural network;
at the awakening phase, conducting a first operation of the awakening phase: supplementing a virtual layer R3 virtual of a symmetric structure with a 1st layer of the convolutional neural network R1 after a 2nd layer of the convolutional neural network R2, and taking R1, R2 and R3 virtual as networks to be trained in the step; training the original data set as input and output of R1, R2 and R3 virtual simultaneously; after training, obtaining weight parameters of R1, and obtaining the output result of R2 as input of a next step of training;
conducting a second operation of the awakening phase: setting l=2;
conducting a third operation of the awakening phase: supplementing a virtual layer Rl+2 virtual of a symmetric structure with Rl after Rl+1, and taking Rl+1, Rl and Rl+2 virtual as networks to be trained in the step; training the output result of Rl in the first operation at the awakening phase as input and output of Rl+1, Rl and Rl+2 virtual simultaneously; after training, obtaining weight parameters of Rl, and obtaining the output result of Rl+1 as input of a next step of training;
conducting a fourth operation of the awakening phase: setting l=l+1, if l<L, jumping to the third operation of the awakening phase; and if l=L, ending the training at the awakening phase, and entering into the sleep phase.

As an optimal solution of the live digital map driven distribution network planning scheme intelligent evaluation method,
training the convolutional neural network by means of using the awakening-sleep mechanism also includes:
at the sleep phase, conducting a first operation of the sleep phase: using the weight of each layer of the convolutional neural network obtained at the awakening phase as an initial weight;
conducting a second operation of the sleep phase: setting input and output of the convolutional neural network according to the original data set; and
conducting a third operation of the sleep phase: training the convolutional neural network by means of using backpropagation to calculate a final weight.

As an optimal solution of the live digital map driven distribution network planning scheme intelligent evaluation method,
calculating four indexes of rate of equipment utilization, power supply radius, installed capacity of renewable energy and peak-valley difference for each alternative planning scheme includes:
rate of equipment utilization: calculating the load curve sum of plots of each transformer substation, so as to obtain a transformer substation load curve Eijtrans, representing the load value of an ith transformer substation at an jth moment; the calculation formula of the rate of equipment utilization is as follows:

$${A}_{1} = average ( max ( {E}_{ij}^{trans} ) / {C}_{i}^{trans} )$$

in the formula, Citrans represents the capacity of the ith transformer substation, max is to calculate the maximum function, and average is to calculate the average function;
power supply radius: calculating the average distance between each plot and respective transformer substations, so as to obtain the power supply radius; the calculation formula is as follows:

$${A}_{2} = average ( {R}_{ij} )$$

in the formula, Rij represents the distance between the ith plot to the jth transformer substation.

As an optimal solution of the live digital map driven distribution network planning scheme intelligent evaluation method,
calculating four indexes of rate of equipment utilization, power supply radius, installed capacity of renewable energy and peak-valley difference for each alternative planning scheme also includes:
installed capacity of renewable energy, expressed as:

$${A}_{3} = sum ( {S}_{i} )$$

in the formula, Si represents the installed capacity of renewable energy of the ith plot, and sum is a summation function;
peak-valley difference, expressed as:

$${A}_{4} = average ( max ( {E}_{ij}^{trans} ) - min ( {E}_{ij}^{trans} ) )$$

in the formula, min is a function to calculate the minimum function value.

As an optimal solution of the live digital map driven distribution network planning scheme intelligent evaluation method,
calculating the weights of the four indexes by means of using the data driven information entropy weight calculating method includes:
calculating the weight Wk of the kth index by means of using the data driven information entropy weight calculating method:

$${W}_{k} = ( 1 - {D}_{k} ) / ( n - sum ( {D}_{k} ) ) \\ {D}_{k} = - {ln ( n )}^{- 1} \times sum ( {A}_{ik} \times ln ( {A}_{ik} ) )$$

in the formula, Dk represents the information entropy of the kth index, n represents the number of indexes, and Aik represents the kth index value of the ith planning scheme.

As an optimal solution of the live digital map driven distribution network planning scheme intelligent evaluation method,
calculating the final score of the alternative planning scheme includes:

$${T}_{i} = sum ( {W}_{k} \times {A}_{ik} )$$

in the formula, Ti represents the final score of an ith scheme.

On a second aspect, an embodiment of the present invention provides a live digital map driven distribution network planning scheme intelligent evaluation system, including:
an acquisition module, configured to acquire live map data and plot type information in the map as the original data set, establishing the U-Net convolutional neural network by means of using the stacked auto-encoder, and taking the original data set as the input of convolutional neural network training;
a training module, configured to train the convolutional neural network by means of using the awakening-sleep mechanism;
an area data calculating module, configured to input live map data of the region to be planned into the convolutional neural network by means of using convolutional neural network parameters obtained through training of the awakening-sleep mechanism, so as to obtain area data of each plot type;
a load curve calculating module, configured to multiplying the typical load curve and the load density of each plot acquired in advance with the obtained plot area, so as to obtain the load curve of each plot;
an index calculating module, configured to calculate, based on the load curve of each plot, four indexes of rate of equipment utilization, power supply radius, installed capacity of renewable energy and peak-valley difference for each alternative planning scheme; and
an evaluation module, configured to calculate weights of four indexes by means of using the data driven information entropy weight calculating method, and calculating the final score of the alternative planning scheme, thereby completing evaluation.

On a third aspect, an embodiment of the present invention provides a calculating device, including:
Memory and processor;
wherein the memory is used for storing computer executable instructions; the processor is used for executing the computer executable instructions; and when one or more programs are executed by one or more processors, the live digital map driven distribution network planning scheme intelligent evaluation method according to any embodiment of the present invention is achieved by one or more processors.

On a fourth aspect, an embodiment of the present invention provides a computer readable storage medium, for storing computer executable instructions, and the live digital map driven distribution network planning scheme intelligent evaluation method is achieved when the computer executable instructions are executed by the processor.

The present invention has the beneficial effects that by means of using live map data and plot type information, with the combination of a deep learning technology, particularly the U-Net convolutional neural network, the area and the load curve of each plot can be precisely inferred, so that the evaluation accuracy is improved; by introducing the awakening-sleep mechanism to train the convolutional neural network, not only is the training efficiency improved, but also the complexity of manually adjusting the network structure is reduced, so that the evaluation process is more efficient and automated; by calculating multiple indexes of rate of equipment utilization, power supply radius, installed capacity of renewable energy and peak-valley difference, advantages and disadvantages of various planning schemes are comprehensively evaluated, and all aspects of demands of the power distribution system can be more comprehensively considered; by adopting the information entropy weight calculating method, weights of the indexes are analyzed according to actual data, and the evaluation can be more objective and scientific; by combining the weights of the indexes with data results of specific schemes, the final score is calculated, and specific bases and ranking are provided for decisions; and the method not only technically improves the precision and efficiency of distribution network planning scheme evaluation, but also is well adaptive to the increasingly complex and efficient energy demands, providing important support and guidance for optimization and future development of the power distribution system.

### BRIEF DESCRIPTION OF DRAWINGS

In order to describe the technical solutions in the examples of the present invention more clearly, a brief description of the accompanying drawings required for describing the examples will be provided below. Obviously, the accompanying drawings in the following description show merely some examples of the present invention. Those of ordinary skill in the art can also derive other accompanying drawings from these accompanying drawings without making creative efforts.

FIG. 1 is an overall flow chat of a live digital map driven distribution network planning scheme intelligent evaluation method of a first embodiment of the present invention;

FIG. 2 is a structural diagram of a U-Net convolutional neural network of a live digital map driven distribution network planning scheme intelligent evaluation method of a first embodiment of the present invention;

FIG. 3 is a schematic diagram of U-Net recognition results and planning schemes of a planning region in a simulation example of a live digital map driven distribution network planning scheme intelligent evaluation method of a second embodiment of the present invention; and

FIG. 4 is a schematic diagram of weight calculation results in a simulation example of a live digital map driven distribution network planning scheme intelligent evaluation method of a second embodiment of the present invention.

### DETAILED DESCRIPTION OF THE EMBODIMENTS

In order to make the aforementioned purposes, features and advantages of the present invention more apparent and comprehensible, detailed descriptions of specific embodiments of the present invention are provided below in conjunction with the appended drawings. It is understood that the described embodiments are merely a part of the embodiments of the present invention, rather than all embodiments. Based on the embodiments of the present invention, all other embodiments obtained by those of ordinary skill in the art without creative efforts shall fall within the protection scope of the present invention.

While the following description provides numerous specific details to fully comprehend the present invention, alternative implementations not explicitly disclosed herein are also possible. Those skilled in the art can carry out similar promotions without deviating from the scope of the present invention, thus the present invention is not limited to the specific embodiments disclosed below.

Secondly, reference herein to “an example” or “example” means a specific feature, structure, or characteristic that can be included in at least one embodiment of the present invention. The term ‘in one embodiment’ appearing in different places in the present specification does not necessarily refer to the same embodiment, nor is it a separate or selective embodiment that is mutually exclusive with other embodiments.

### Embodiment 1

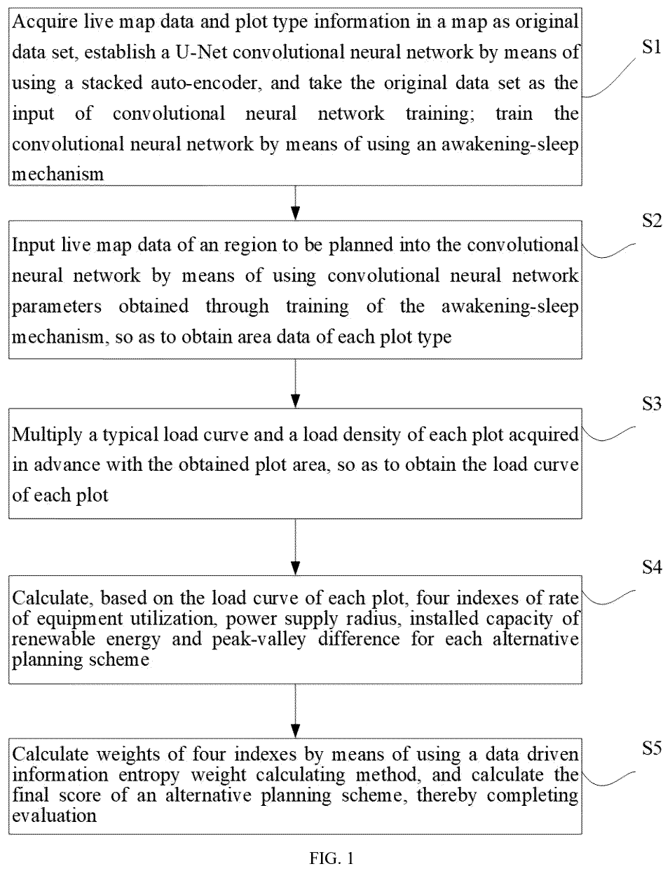

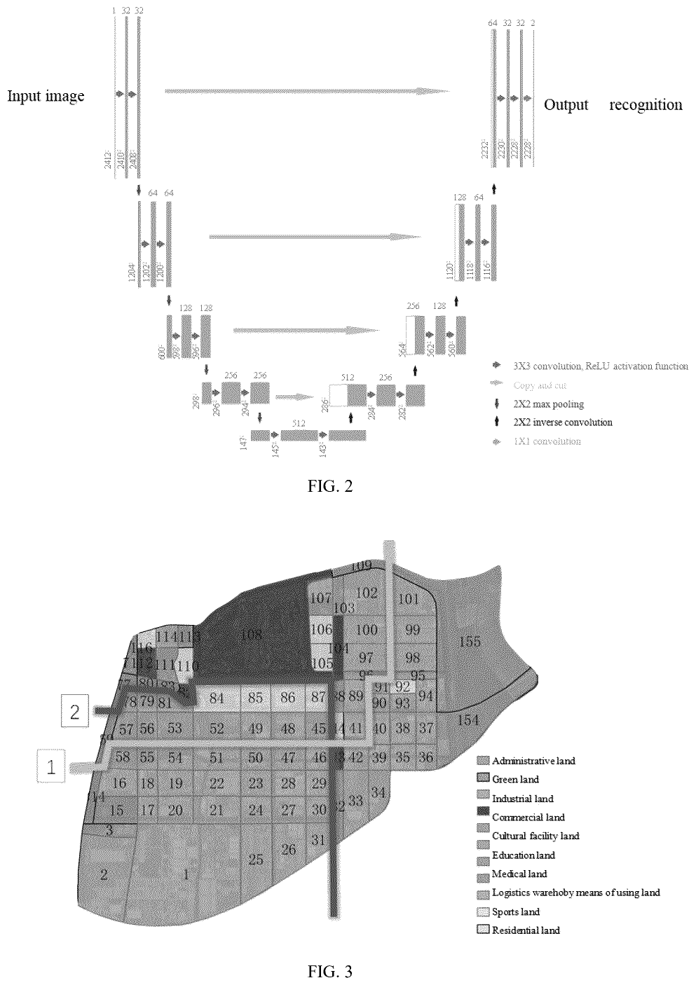

Referring to FIG. 1-2, as a first embodiment of the present invention, the embodiment provides a live digital map driven distribution network planning scheme intelligent evaluation method, including:

S1: acquiring live map data and plot type information in a map as original data set, establishing a U-Net convolutional neural network by means of using a stacked auto-encoder, and taking the original data set as the input of convolutional neural network training; training the convolutional neural network by means of using an awakening-sleep mechanism;
in the embodiment of the present application, training the
convolutional neural network by means of using the awakening-sleep mechanism includes:
dividing training into two phases of awakening and sleep; setting Ri as the ith layer of the convolutional neural network, and L as the number of layers of the convolutional neural network;
at the awakening phase, conducting a first operation of the awakening phase: supplementing a virtual layer R3 virtual of a symmetric structure with a 1st layer of the convolutional neural network R1 after a 2nd layer of the convolutional neural network R2, and taking R1, R2 and R3 virtual as networks to be trained in the step; training the original data set as input and output of R1, R2 and R3 virtual simultaneously; after training, obtaining weight parameters of R1, and obtaining the output result of R2 as input of a next step of training;
conducting a second operation of the awakening phase: setting l=2;
conducting a third operation of the awakening phase: supplementing a virtual layer Rl+2 virtual of a symmetric structure with Rl after Rl+1, and taking Rl+1, Rl and Rl+2 virtual as networks to be trained in the step; training the output result of Rl in the first operation at the awakening phase as input and output of Rl+1, Rl and Rl+2 virtual simultaneously; after training, obtaining weight parameters of Rl, and obtaining the output result of Rl+1 as input of a next step of training;
conducting a fourth operation of the awakening phase: setting l=l+1, if l<L, jumping to the third operation of the awakening phase; and if l=L, ending the training at the awakening phase, and entering into the sleep phase. at the sleep phase, conducting a first operation of the sleep phase: using the weight of each layer of the convolutional neural network obtained at the awakening phase as an initial weight;
conducting a second operation of the sleep phase: setting input and output of the convolutional neural network according to the original data set; and
conducting a third operation of the sleep phase: training the convolutional neural network by means of using backpropagation to calculate a final weight.

What needs to be noted is that the awakening-sleep mechanism effectively improves the training efficiency and convergence speed of the convolutional neural network, making the model reach a better performance level faster in complex tasks. By means of using the live map data and plot type information as input, combined with the convolutional neural network trained by awakening-sleep mechanism, the model can infer the area and the load curve of the plot more accurately, thus improving the accuracy and reliability of the evaluation results. Not only are the evaluation automation and efficiency of distribution network planning schemes technically improved, but also the integration and operability of the model are fully considered in the implementation process, providing a reliable solution for practical applications.

S2: inputting live map data of an region to be planned into the convolutional neural network by means of using convolutional neural network parameters obtained through training of the awakening-sleep mechanism, so as to obtain area data of each plot type;

Specifically, the live map data need to be preprocessed: ensuring that the live map data of the region to be planned are accordant with data types and format used in training, including image resolution, color space, and the like; and embedding the plot type information into input data in an appropriate format, so as to ensure that the convolutional neural network can effectively identify and analyze plots of different types.

What needs to be noted is that through the trained convolutional neural network, area data of each plot can be precisely inferred, and the data are one of key input of subsequent load curve calculation and evaluation process.

S3: multiplying a typical load curve and a load density of each plot acquired in advance with the obtained plot area, so as to obtain the load curve of each plot;

What needs to be noted is that with the combination of the typical load curve and the plot area data, the load curve obtained has high precision and reliability, and load characteristics of each plot can be accurately reflected. The load curve is an important input parameter for evaluating each alternative planning scheme, and the precise calculation thereof is helpful to accurately evaluate the power demand and system load of each scheme.

S4: calculating, based on the load curve of each plot, four indexes of rate of equipment utilization, power supply radius, installed capacity of renewable energy and peak-valley difference for each alternative planning scheme.

In the embodiment of the present application, calculating four indexes of rate of equipment utilization, power supply radius, installed capacity of renewable energy and peak-valley difference for each alternative planning scheme includes:
rate of equipment utilization: calculating the load curve sum of plots of each transformer substation, so as to obtain a transformer substation load curve Eijtrans, representing the load value of an ith transformer substation at an jth moment; the calculation formula of the rate of equipment utilization is as follows:

$${A}_{1} = average ( max ( {E}_{ij}^{trans} ) / {C}_{i}^{trans} )$$

in the formula, Citrans represents the capacity of the ith transformer substation, max is to calculate the maximum function, and average is to calculate the average function;
power supply radius: calculating the average distance between each plot and respective transformer substations, so as to obtain the power supply radius; the calculation formula is as follows:

$${A}_{2} = average ( {R}_{ij} )$$

in the formula, Rij represents the distance between the ith plot to the jth transformer substation.
installed capacity of renewable energy, expressed as:

$${A}_{3} = sum ( {S}_{i} )$$

in the formula, Si represents the installed capacity of renewable energy of the ith plot, and sum is a summation function;
peak-valley difference, expressed as:

$${A}_{4} = average ( max ( {E}_{ij}^{trans} ) - min ( {E}_{ij}^{trans} ) )$$

in the formula, min is a function to calculate the minimum function value.

S5: calculating weights of four indexes by means of using a data driven information entropy weight calculating method, and calculating the final score of an alternative planning scheme, thereby completing evaluation.

In the embodiment of the present application, calculating the weights of the four indexes by means of using the data driven information entropy weight calculating method includes:
calculating the weight Wk of the kth index by means of using the data driven information entropy weight calculating method:

$${W}_{k} = ( 1 - {D}_{k} ) / ( n - sum ( {D}_{k} ) ) \\ {D}_{k} = - {ln ( n )}^{- 1} \times sum ( {A}_{ik} \times ln ( {A}_{ik} ) )$$

in the formula, Dk represents the information entropy of the kth index, n represents the number of indexes, and Aik represents the kth index value of the ith planning scheme.
calculating the final score of the alternative planning scheme includes:

$${T}_{i} = sum ( {W}_{k} \times {A}_{ik} )$$

in the formula, Ti represents the final score of an ith scheme.

What needs to be noted is that calculating the weight by means of using the information entropy method can objectively reflect the contribution of each index to the final evaluation result, and avoid the bias of subjective weighting. Comprehensive consideration of multiple indexes of the rate of equipment utilization, power supply radius, installed capacity of renewable energy, peak-valley difference and the like ensures the comprehensiveness and integrity of evaluation results. The final score provides intuitive and quantitative evaluation results, provides a specific planning scheme ranking basis for decision makers, and supports the scientificity and operability of decisions.

The above is a schematic solution of the live digital map driven distribution network planning scheme intelligent evaluation method of the embodiment. What needs to be noted is that the technical solution of the live digital map driven distribution network planning scheme evaluation system belongs to the same idea as the technical solution of the live digital map driven distribution network planning scheme intelligent evaluation method. Detailed contents which are not specifically described in the technical solution of the live digital map driven distribution network planning scheme intelligent evaluation system of the embodiment can refer to the description of the technical solution of the live digital map driven distribution network planning scheme intelligent evaluation method.

The live digital map driven distribution network planning scheme intelligent evaluation system of the embodiment, including:
an acquisition module, configured to acquire live map data and plot type information in the map as the original data set, establishing the U-Net convolutional neural network by means of using the stacked auto-encoder, and taking the original data set as the input of convolutional neural network training;
a training module, configured to train the convolutional neural network by means of using the awakening-sleep mechanism;
an area data calculating module, configured to input live map data of the region to be planned into the convolutional neural network by means of using convolutional neural network parameters obtained through training of the awakening-sleep mechanism, so as to obtain area data of each plot type;
a load curve calculating module, configured to multiplying the typical load curve and the load density of each plot acquired in advance with the obtained plot area, so as to obtain the load curve of each plot;
an index calculating module, configured to calculate, based on the load curve of each plot, four indexes of rate of equipment utilization, power supply radius, installed capacity of renewable energy and peak-valley difference for each alternative planning scheme; and
an evaluation module, configured to calculate weights of four indexes by means of using the data driven information entropy weight calculating method, and calculating the final score of the alternative planning scheme, thereby completing evaluation.

The embodiment also provides a calculating device, applicable to situations of the live digital map driven distribution network planning scheme intelligent evaluation method, including:
a memory and a processor, wherein the memory is used for storing computer executable instructions, and the processor is used for executing the computer executable instructions, to achieve the live digital map driven distribution network planning scheme intelligent evaluation method disclosed by the embodiment.

The embodiment also provides a storage medium, where computer programs are stored, and the live digital map driven distribution network planning scheme intelligent evaluation method disclosed by the embodiment is achieved when the programs are executed by the processor.

The storage medium disclosed by the embodiment belongs to the same idea as the live digital map driven distribution network planning scheme intelligent evaluation method disclosed by the embodiment. Technical details which are not specifically described in the embodiment refer to the embodiment, and the embodiment has the same beneficial effects as those of the embodiment above.

### Embodiment 2

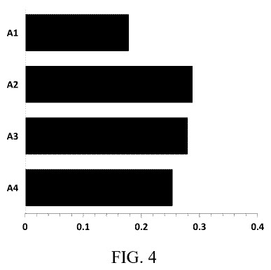

Referring to FIG. 3-4 and Table 1, as an embodiment of the present invention, providing a live digital map driven distribution network planning scheme intelligent evaluation method, to verify the beneficial effect of the present invention, scientific demonstration is carried out through simulation experiments.

1. Data preparation and preprocessing

Acquiring live map data and plot type information as the original data set; and preparing a typical load curve and load density data.

2. Establishment of U-Net convolutional neural network

Establishing the convolutional neural network of a U-Net structure by means of using an auto-encoder; and taking the live map data as training input to predict the area data of each plot type.

3. Training with the awakening-sleep mechanism

Awakening phase:

Sequentially adding the virtual layer, and training a network to obtain weight parameters of each layer.

Sleep phase:

Taking the weight parameters obtained at the awakening phase as initial weights; and further optimizing network parameters by means of using a backpropagation algorithm.

4. Calculation of load curve

Calculating the load curve of each plot based on predicted plot area data and load density.

5. Calculation of performance index

Calculating the following four indexes: rate of equipment utilization A1, power supply radius A2, installed capacity of renewable energy A3 and peak-valley difference A4 for each alternative planning scheme.

6. Calculation of information entropy weight

Calculating the weights of the four indexes by means of using the data driven information entropy weight calculating method.

7. Evaluation of planning scheme

According to calculated weights and index values, calculating the final score Ti of each planning scheme.

As shown in FIG. 3, plot recognition situations and planning schemes of the planning region are shown, and these information directly affects input data and training process of the U-Net model. The weight calculation result shown in FIG. 4 affects the final planning scheme evaluation, and the importance of different indexes in evaluation is reflected by the weights calculated by means of using the information entropy calculating method. The following is partial experiment results:

TABLE 1
Partial experiment results

| Serial | Rate of | Power | installed | | |
|---|---|---|---|---|---|
| number of | equipment | supply | capacity of | Peak-valley | Final |
| planning | utilization | radius | renewable | difference | score |
| scheme | (A₁) | (A₂) | energy (A₃) | (A₄) | (Tᵢ) |
| 1 | 0.82 | 15 km | 100 MW | 50 kW | 0.76 |
| 2 | 0.78 | 18 km | 120 MW | 55 kW | 0.72 |
| 3 | 0.85 | 12 km | 90 MW | 45 kW | 0.78 |

Through simulation examples, the effectiveness and practicability of the live digital map driven distribution network planning scheme intelligent evaluation method are demonstrated, and important technical support and decision making bases are provided for intelligent planning in actual application scenes.

It should be noted that the above examples are merely used to explain the technical solutions of the present invention and not intended to limit the present disclosure. Although the present invention is described in detail with reference to the preferred examples, those of ordinary skill in the art should understand that they can make modifications or equivalent substitutions to the technical solutions of the present invention without departing from the spirit and scope of the technical solutions of the present invention. These modifications or equivalent substitutions should fall within the scope of the claims of the present invention.

What is claimed is:

1. A live digital map driven distribution network planning scheme intelligent evaluation method, comprising:
acquiring live map data and plot type information in a map as original data set, establishing a U-Net convolutional neural network by means of using a stacked auto-encoder, and taking the original data set as the input of convolutional neural network training;
training the convolutional neural network by means of using an awakening-sleep mechanism;
inputting live map data of a region to be planned into the convolutional neural network by means of using convolutional neural network parameters obtained through training of the awakening-sleep mechanism, so as to obtain area data of each plot type;
multiplying a typical load curve and a load density of each plot acquired in advance with the obtained plot area, so as to obtain the load curve of each plot;
calculating, based on the load curve of each plot, four indexes of rate of equipment utilization, power supply radius, installed capacity of renewable energy and peak-valley difference for each alternative planning scheme; and
calculating weights of four indexes by means of using a data driven information entropy weight calculating method, and calculating the final score of an alternative planning scheme, thereby completing evaluation.

2. The live digital map driven distribution network planning scheme intelligent evaluation method according to claim 1, wherein the training the convolutional neural network by means of using the awakening-sleep mechanism comprises:
dividing training into two phases of awakening and sleep; setting Rᵢ as the i th layer of the convolutional neural network, and L as the number of layers of the convolutional neural network;
at the awakening phase, conducting a first operation of the awakening phase:
supplementing a virtual layer R₃^{virtual} of a symmetric structure with a 1st layer of the convolutional neural network R₁ after a 2nd layer of the convolutional neural network R₂, and taking R₁, R₂ and R₃^{virtual} as networks to be trained in the step; training the original data set as input and output of R₁, R₂ and R₃^{virtual} simultaneously; after training, obtaining weight parameters of R₁, and obtaining the output result of R₂ as input of a next step of training;
conducting a second operation of the awakening phase: setting l=2;
conducting a third operation of the awakening phase: supplementing a virtual layer Rₗ₊₂^{virtual} of a symmetric structure with Rₗ after Rₗ₊₁, and taking Rₗ₊₁, Rₗ and Rₗ₊₂^{virtual} as networks to be trained in the step; training the output result of Rₗ in the first operation at the awakening phase as input and output of Rₗ₊₁, Rₗ and Rₗ₊₂^{virtual} simultaneously; after training, obtaining weight parameters of Rₗ, and obtaining the output result of Rₗ₊₁ as input of a next step of training;
conducting a fourth operation of the awakening phase: setting l=l+1, if l<L, jumping to the third operation of the awakening phase; and if l=L, ending the training at the awakening phase, and entering into the sleep phase.

3. The live digital map driven distribution network planning scheme intelligent evaluation method according to claim 2, wherein the training the convolutional neural network by means of using the awakening-sleep mechanism also comprises:
at the sleep phase, conducting a first operation of the sleep phase: using the weight of each layer of the convolutional neural network obtained at the awakening phase as an initial weight;
conducting a second operation of the sleep phase: setting input and output of the convolutional neural network according to the original data set; and
conducting a third operation of the sleep phase: training the convolutional neural network by means of using backpropagation to calculate a final weight.

4. The live digital map driven distribution network planning scheme intelligent evaluation method according to claim 3, wherein the calculating four indexes of rate of equipment utilization, power supply radius, installed capacity of renewable energy and peak-valley difference for each alternative planning scheme comprises:
rate of equipment utilization: calculating the load curve sum of plots of each transformer substation, so as to obtain a transformer substation load curve Eᵢⱼ^{trans}, representing the load value of an ith transformer substation at an jth moment; the calculation formula of the rate of equipment utilization is as follows:
$${A}_{1} = average ( max ( {E}_{ij}^{trans} ) / {C}_{i}^{trans} )$$
in the formula,
$${C}_{i}^{trans}$$
represents the capacity of the ith transformer substation, max is to calculate the maximum function, and average is to calculate the average function;
power supply radius: calculating the average distance between each plot and respective transformer substations, so as to obtain the power supply radius; the calculation formula is as follows:
$${A}_{2} = average ( {R}_{ij} )$$
in the formula, Rᵢⱼ represents the distance between the ith plot to the jth transformer substation.

5. The live digital map driven distribution network planning scheme intelligent evaluation method according to claim 4, wherein the calculating four indexes of rate of equipment utilization, power supply radius, installed capacity of renewable energy and peak-valley difference for each alternative planning scheme also comprises:
installed capacity of renewable energy, expressed as:
$${A}_{3} = sum ( {S}_{i} )$$
in the formula, Sᵢ represents the installed capacity of renewable energy of the ith plot, and sum is a summation function;
peak-valley difference, expressed as:
$${A}_{4} = average ( max ( {E}_{ij}^{trans} ) - min ( {E}_{ij}^{trans} ) )$$
in the formula, min is a function to calculate the minimum function value.

6. The live digital map driven distribution network planning scheme intelligent evaluation method according to claim 5, wherein the calculating weights of four indexes by means of using the data driven information entropy weight calculating method comprises:
calculating the weight Wₖ of the kth index by means of using the data driven information entropy weight calculating method:
$${W}_{k} = ( 1 - {D}_{k} ) / ( n - sum ( {D}_{k} ) ) \\ {D}_{k} = - {ln ( n )}^{- 1} \times sum ( {A}_{ik} \times ln ( {A}_{ik} ) )$$
in the formula, Dₖ represents the information entropy of the kth index, n represents the number of indexes, and Aᵢₖ represents the kth index value of the ith planning scheme.

7. The live digital map driven distribution network planning scheme intelligent evaluation method according to claim 6, wherein calculating the final score of an alternative planning scheme comprises:
$${T}_{i} = sum ( {W}_{k} \times {A}_{ik} )$$
in the formula, Tᵢ represents the final score of an ith scheme.

8. A system adopting the live digital map driven distribution network planning scheme intelligent evaluation method according to claim 1, comprising:
an acquisition module, configured to acquire live map data and plot type information in the map as the original data set, establishing the U-Net convolutional neural network by means of using the stacked auto-encoder, and taking the original data set as the input of convolutional neural network training;
a training module, configured to train the convolutional neural network by means of using the awakening-sleep mechanism;
an area data calculating module, configured to input live map data of the region to be planned into the convolutional neural network by means of using convolutional neural network parameters obtained through training of the awakening-sleep mechanism, so as to obtain area data of each plot type;
a load curve calculating module, configured to multiplying the typical load curve and the load density of each plot acquired in advance with the obtained plot area, so as to obtain the load curve of each plot;
an index calculating module, configured to calculate, based on the load curve of each plot, four indexes of rate of equipment utilization, power supply radius, installed capacity of renewable energy and peak-valley difference for each alternative planning scheme; and
an evaluation module, configured to calculate weights of four indexes by means of using the data driven information entropy weight calculating method, and calculating the final score of the alternative planning scheme, thereby completing evaluation.

9. A calculating device, comprising:
a memory and a processor,
wherein the memory is used for storing computer executable instructions; the processor is used for executing the computer executable instructions; and steps of the live digital map driven distribution network planning scheme intelligent evaluation method according to claim 1 are achieved when the computer executable instructions are executed by the processor.

10. A computer readable storage medium, for storing computer executable instructions, wherein steps of the live digital map driven distribution network planning scheme intelligent evaluation method according to of claim 1 are achieved when the computer executable instructions are executed by the processor.
